(19) United States
(12) Patent Application Publication
(10) Pub. No.: US 2006/0118243 A1
(43) Pub. Date: Jun. 8, 2006

(54) Wafer support having cooling passageway for cooling a focus ring in plasma processing equipment

(76) Inventor: Min-woong Choi, Yongin-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/193,327

(22) Filed: Aug. 1, 2005

(30) Foreign Application Priority Data
Dec. 2, 2004 (KR) 10-2004-0100359

(51) Int. Cl. H01L 21/306

(52) U.S. Cl. 156/345.51; 156/915

(57) ABSTRACT

A wafer support keeps a focus ring cool during an etching process to prevent the temperature from varying across a wafer being etched. The wafer support includes a main body in which a cooling passage is defined. The main body has a first top surface on which a wafer is supported and a second top surface atop which the focus ring is disposed. The cooling passage has a first cooling passageway extending directly under the first top surface to cool the wafer and a second cooling passageway extending directly under the second top surface to cool the focus ring.

### BACKGROUND OF THE INVENTION

1. Field of the Invention

The present invention relates to semiconductor manufacturing equipment. More particularly, the present invention relates to plasma processing equipment and to the structure that supports a wafer in such equipment.

2. Description of the Related Art

Many pieces of equipment are used for manufacturing a semiconductor device. One of these pieces of equipment is a dry etching apparatus. In dry etching, a wafer is exposed to plasma to selectively remove a surface layer, such as a silicon oxide layer, from the wafer. The dry etching apparatus comprises a reaction chamber, and a wafer support such as an electrostatic chuck (ESC) for holding the wafer in the reaction chamber.

However, a wafer can become overheated during the etching process. Therefore, the ESC has a cooling passage connected to a chiller to cool the wafer.

FIG. 1 is a sectional view of a conventional ESC having a cooling passage. Referring to FIG. 1, the main body 20 of the ESC supports a wafer 10. A lower electrode 30 is fixed by screws 61 to the bottom of the main body 20.

An upper electrode (not shown) is disposed in the reaction chamber above the ESC and is connected to a power source. In addition, a system is provided for introducing source gas into the reaction chamber. The source gas fed into the reaction chamber is excited by the power supplied to the upper electrode. As a result, the source gas is converted to plasma. In this respect, power at a frequency of about 60 Mhz may be applied to the upper electrode. Also, a bias power at a frequency of about 2 Mhz may be applied to the lower electrode 30 to accelerate the plasma towards the wafer 10. Accordingly, the plasma etches the wafer 10.

The top of the main body 20 of the ESC is stepped. In particular, the main body 20 has a first top surface 21, and a second top surface 25 that extends around the first top surface 21 at a level beneath that of the first top surface 21. The wafer 10 is loaded onto the first top surface 21. Screw holes extend through the main body 20 of the ESC and open at the second top surface 25 to receive the screws 61. The wafer 10 has a diameter larger than that the first top surface 21 and thus, an outer peripheral portion of the wafer 10 does not contact the first top surface 21. For example, the wafer 10 protrudes 2 mm beyond the edge of the first top surface 21.

A focus ring 40 is disposed around the main body 20 of the ESC to prevent the etchant (plasma) from concentrating at the outer peripheral portion of the wafer 10. The focus ring 40 has a first top surface 41, and a second top surface 45 disposed at a level beneath that of the first top surface 41. The outer peripheral portion of the wafer 10 extends over the second top surface 45 of the focus ring 40. The first top surface 41 of the focus ring 40 in effect extends the silicon region of wafer 10 to prevent the etchant (plasma) from concentrating at the edge of the wafer 10. A base 65 is disposed under the focus ring 40.

In addition, the main body 20 of the ESC has a cooling passage 50 extending therethrough. Coolant is circulated through the cooling passage 50 to prevent the wafer 10 from overheating of during the etching process. The cooling passage 50 extends under the first top surface 21 but not under the second top surface 25. Therefore, the focus ring 40 is hardly cooled by the coolant circulating through the cooling passage 50 and hence, the outer peripheral portion of the wafer 10 is not cooled sufficiently. This may result in a partial overheating of and/or a non-uniform temperature distribution across the wafer 10.

FIG. 2 shows such a non-uniform temperature distribution across a wafer while the wafer is being etched on a conventional wafer support. As can be seen in FIG. 2, the temperature of the wafer varies significantly from the center to the edge of the wafer. The wafer may be etched non-uniformly due to this temperature difference, whereby the critical dimension (CD) of the resulting pattern is non-uniform.

### SUMMARY OF THE INVENTION

Therefore, one object of the present invention is to provide a wafer support that can uniformly cool a wafer.

Another object of the present invention is to provide plasma processing equipment in which a wafer can be processed, e.g., etched, uniformly across a surface thereof.

According to one aspect of the present invention, there is provided wafer support structure capable of cooling both a wafer and a focus ring that is disposed around the wafer, during an etching process. The wafer support structure comprises the focus ring, and a wafer support. The wafer support includes a main body having a first top surface configured to support the wafer, and a second top surface that extends around the wafer and above which the focus ring is located. The main body defines a cooling passage which includes a first cooling passageway extending directly under the first top surface to cool the wafer and a second cooling passageway extending directly under the second top surface to cool the focus ring.

According to another aspect of the present invention, there is provided a wafer support that is capable of cooling both the center and an outer peripheral portion of a wafer during an etching process, such that the temperature distribution across the wafer is kept uniform. The wafer support includes a main body having a first top surface configured to support a wafer and located at a central portion of the main body, and a second top surface extending around the first top surface at a level beneath that at which the first top surface is disposed. Thus, an upper portion of the main body is stepped so that an outer peripheral portion of the wafer will extend outwardly from the periphery of the first top surface. The main body defines a cooling passage made up of a first cooling passageway running directly under the first top surface to cool the central portion of the wafer and a second cooling passageway running directly under the second top surface to cool the outer peripheral portion of the wafer.

According to still another aspect of the present invention, there is provided plasma processing equipment that includes the aforementioned wafer support structure. In general, the plasma processing equipment also comprises a reaction chamber having a gas inlet through which process gas is introduced into the chamber, and a gas outlet through which gas in the chamber is exhausted, and a plasma generator for exciting the process gas introduced into the reaction chamber. The wafer support structure is disposed within the reaction chamber beneath the plasma generator.

The first cooling passage defined by the main body of the wafer support structure may have a circular section running approximately directly beneath the periphery of the first top surface of the main body and a cross-shaped section disposed inwardly of the circular section. The second cooling passageway may be circular and thereby encircle the first cooling passageway.

The main body may also define a coolant inlet hole by which coolant is fed into the first cooling passageway. In this case, the second cooling passageway branches from the first cooling passageway proximate the coolant inlet hole. The main body may also define a first coolant outlet hole and a second coolant outlet hole. The first coolant outlet hole is open at the first top surface of the main body and is connected to the first cooling passageway such that coolant flowing through the first cooling passageway may be discharged from the main body. The second coolant outlet hole is open at the second top surface of the main body and is connected to the second cooling passageway such that coolant flowing through the second cooling passageway can be discharged from the main body.

### BRIEF DESCRIPTION OF THE DRAWINGS

The above and other objects, features and advantages of the present invention will become more apparent from the following detailed description of the preferred embodiments thereof made with reference to the attached drawings in which:

FIG. 1 is a cross-sectional view of conventional wafer support structure whose main body has a cooling passage extending therethrough;

FIG. 2 is a plan view of an image of a wafer showing a non-uniform temperature distribution that is present across the wafer when the conventional wafer support is used;

FIG. 3 is a cross-sectional view of wafer support structure according to the present invention;

FIG. 4 is a sectional view of a main body of the wafer support structure according to the present invention; and

FIG. 5 is a schematic diagram of plasma processing equipment that includes a wafer support according to the present invention.

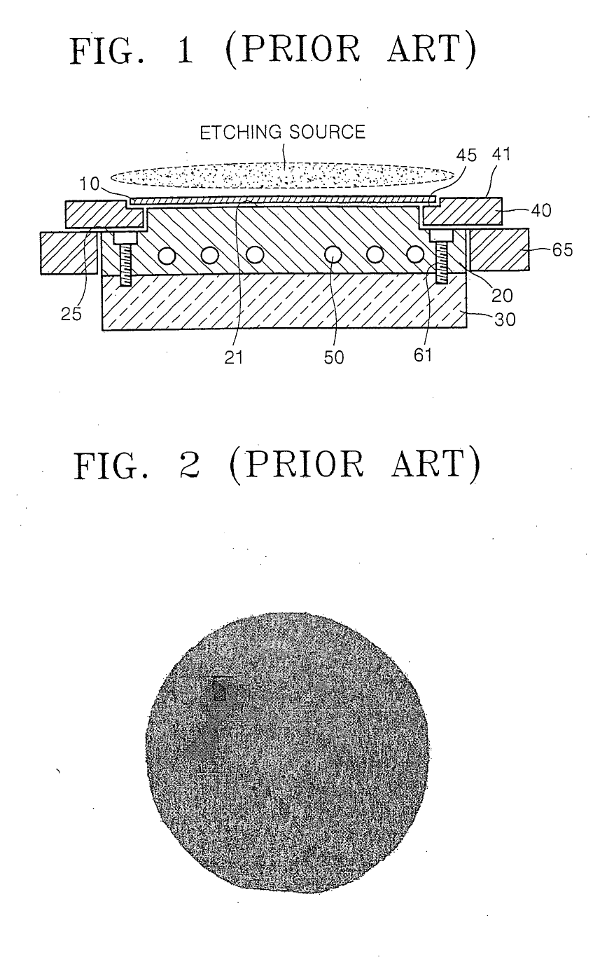

### DETAILED DESCRIPTION OF THE PREFERRED EMBODIMENTS

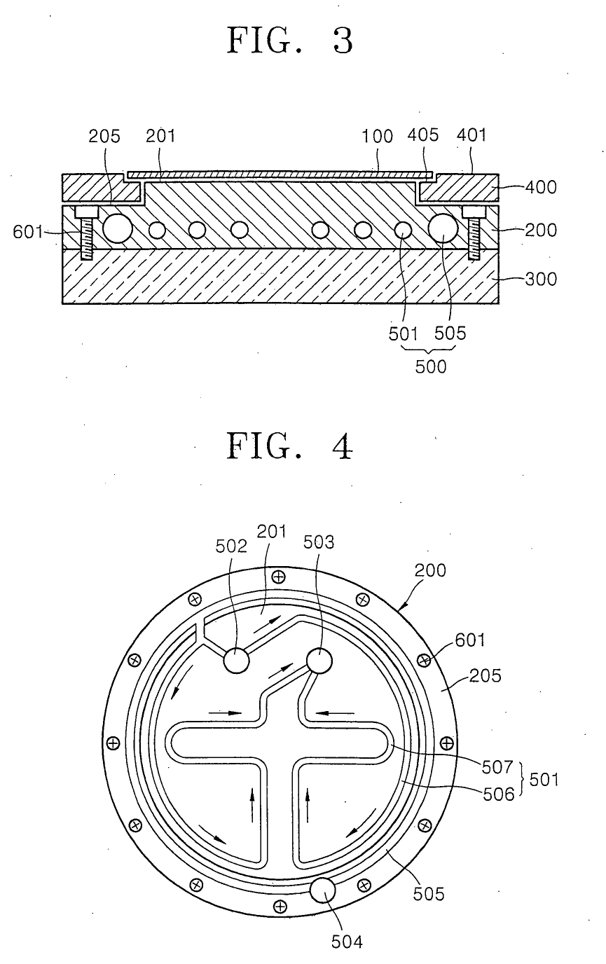

Referring to FIGS. 3-5, a wafer support of the present invention supports and holds a wafer in a reaction chamber 50 during an etching process. The wafer support may be an ESC. The ESC includes a main body 200 onto which a wafer 100 is loaded, and a lower electrode 300 attached to the main body 200. The main body 200 has a first top surface 201 and a second top surface 205. The lower electrode 300 is fixed to a bottom of the main body 200 by means of screws 601. A focus ring 400 is disposed around the main body 200.

The main body 200 defines a cooling passage 500 through which coolant is circulated to cool the wafer 100. A portion of the cooling passage 500 extends directly beneath the focus ring 400. More specifically, the cooling passage 500 includes a first cooling passageway 501 and a second cooling passageway 505. The first cooling passageway 501 is disposed directly beneath the first top surface 201 on which the wafer 100 rests, and the second cooling passageway 505 is disposed directly beneath the second top surface 205.

The first top surface 201 is disposed at the central portion of the main body 200, and the second top surface 205 is disposed at an outer circumferential portion of the main body 200. The second top surface 205 extends at a level beneath that at which the first top surface 201 extends. That is, the upper portion of the main body 200 is stepped. Screw holes extend through the outer circumferential portion of the main body 200 and open at the second top surface 205 to receive the screws 601 that fix the lower electrode 300 to the main body 200. In general, the first top surface 201 has a diameter smaller than that of the wafer 100. In particular, the wafer 100 will typically protrude by about 2 mm from the first top surface 201.

The focus ring 400 is disposed on the second top surface 205 of the main body 200 so as to extend around the wafer 100. The focus ring 400 has a first top surface 401 and a second top surface 405 that is substantially coplanar with the first top surface 201 of the main body 200. The first top surface 401 of the focus ring 400 will form an extension of the wafer 100 to prevent the outer peripheral portion of the wafer 100 from being etched to a greater extent than a central portion of the wafer 100. The focus ring 400 is made of material similar to that of the wafer 100, for example, silicon.

The first top surface 401 and second top surface 405 of the focus ring 400 may be disposed at different levels, as shown in the drawings. Also, the first top surface 401 of the focus ring 400 may be situated at a level above or below the top surface of the wafer 100 when the wafer is supported on the first top surface 201 of the main body 200. Still further, the first top surface 401 of the focus ring 400 may be disposed at a level above or below that at which the first top surface 201 of the main body 200 is disposed. In addition, the second top surface 405 of the focus ring 400 may extend beneath the wafer 100.

As mentioned above, the second cooling passageway 505 of the main body 200 is defined directly beneath the focus ring 400. Specifically, the second cooling passageway 505 may be located under the second top surface 405 of the focus ring 400. It will thus be understood that the first cooling passageway 501 of the main body 200 is designed to facilitate the cooling of the wafer 100 whereas the second cooling passageway 505 is designed to facilitate the cooling of the focus ring 400.

More specifically, a coolant such as liquid helium is circulated through the second cooling passageway 505 to cool the focus ring 400 and thereby also cool the outer peripheral portion of the wafer. Therefore, the central and outer peripheral portions of the wafer 100 can be uniformly cooled so that the temperature distribution across the wafer 100 can be kept uniform and low during the etching process.

The first cooling passageway 501 of the main body 200 may include a circular section 506 and a cross-shaped section 507. The circular section 506 may extend approximately under the outer peripheral edge of the first top surface 201, and the cross-shaped section 507 may extend inwardly of the circular section 506 to cool the entire wafer 100 uniformly.

The main body 200 also defines a coolant inlet hole 502, a first coolant outlet hole 503, and a second coolant outlet hole 504 open at the exterior of the main body 200, namely, at the bottom surface of the main body 200. Coolant supply and drain lines/passages may extend through the lower electrode 300 to the inlet and outlet holes 502, 503, 504, respectively, such that coolant can be supplied to the coolant inlet hole 502 and drained from the coolant outlet holes 503 and 504. The first cooling passageway 501 runs from the coolant inlet hole 502 to the first coolant outlet hole 503, such that some of the coolant entering the main body 200 via the coolant inlet hole 502 flows through the first cooling passageway 501 to the first coolant outlet hole 503. Also, the second cooling passageway 505 branches off from the first cooling passageway 501 at the coolant inlet hole 502 and ends at the first coolant outlet hole 503. Thus, some of the coolant entering the main body 200 via the coolant inlet hole 502 flows through the second cooling passageway 505 to the second coolant outlet hole 504. In an alternative embodiment, the first cooling passageway 501 and the second cooling passageway 505 may join together at the first coolant outlet hole 503 such that coolant flowing along the cooling passageways 501 and 505 may exit the main body 200 via the first coolant outlet hole 503.

The shape of the cooling passageway 501 and the locations of the coolant inlet and outlet holes 502, 503 and 504 may differ from that shown in the figures and described above. In particular, the shape of the cooling passage 500, and especially of the first cooling passageway 501, may be designed to facilitate an efficient and uniform cooling of the wafer. Furthermore, the coolant inlet hole 502, the first coolant outlet hole 503, and the second coolant outlet hole 504 may be located at positions that also facilitate an efficient and uniform cooling of the wafer.

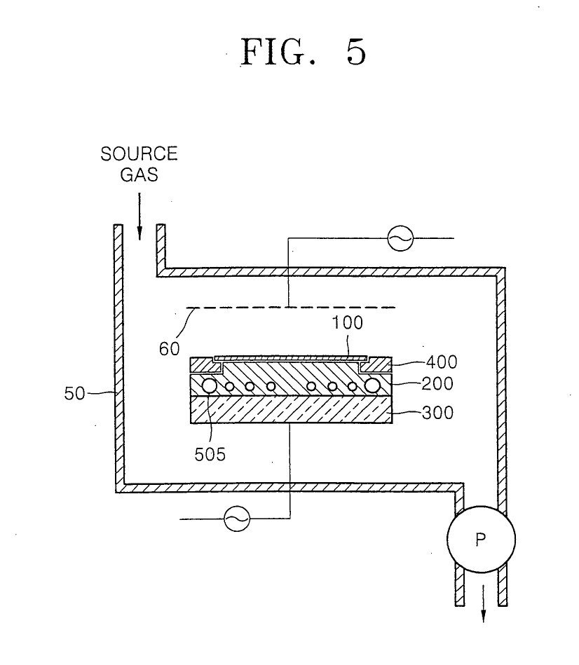

Referring in particular to FIG. 5, the plasma processing equipment also includes an upper electrode 60 disposed in the reaction chamber 50 above the wafer support structure. The upper electrode 60 is connected to a power source. Alternatively, an inductive coil connected to an RF power source, i.e., an Inductive Coupled Plasma (ICP) coil, maybe provided at an upper part of the reaction chamber. In addition, a system is provided for introducing source gas into the reaction chamber. The source gas fed into the reaction chamber is excited by the power supplied to the upper electrode 60. As a result, the source gas is converted to plasma. Also, a power source is connected to the lower electrode 300 to apply a bias power to the lower electrode 30 such that the plasma is accelerated towards the wafer 100. Accordingly, the plasma etches the wafer 10. By-products and the like are exhausted form the reaction chamber 50 through an exhaust opening to which a vacuum pump or the like is connected.

According to the present invention, the second cooling passageway 505 extends directly under the focus ring 400 to enhance the cooling of the outer peripheral portion of the wafer 100 that is located beside and/or directly above the focus ring 400. Therefore, the wafer 100 can be cooled uniformly during the etching process, i.e., without the temperature difference arising between the outer peripheral and central portions of the wafer. As a result, the etching can be carried out more effectively and more precisely.

Finally, although the present invention has been particularly shown and described with reference the preferred embodiments thereof, various changes in form and details may be made thereto without departing from the true spirit and scope of the present invention as defined by the following claims.

What is claimed is:

1. Wafer support structure of semiconductor wafer processing equipment, comprising:
an annular focus ring; and
a wafer support including a main body having a first top surface configured to support a wafer, and a second top surface extending around the first top surface, the focus ring being disposed directly over the second top surface, and said main body defining a cooling passage therein,
the cooling passage including a first cooling passageway running directly beneath the first top surface such that coolant flowing through the first cooling passageway will cool a wafer resting on the first top surface, and a second cooling passageway running directly beneath the second top surface such that coolant flowing through the second cooling passageway will cool the focus ring.

2. The wafer support structure of claim 1, wherein the focus ring has a first top surface, and a second top surface that is substantially coplanar with the first top surface of the main body of the wafer support, the second top surface of the focus ring being disposed at a level beneath that at which the first top surface of the focus ring is disposed.

3. The wafer support structure of claim 1, wherein the first top surface of the main body has a circular outer periphery, and the first cooling passageway has a circular section running approximately directly under the circular periphery of the first top surface of the main body, and a cross-shaped section located radially inwardly of the circular section.

4. The wafer support structure of claim 1, wherein the second cooling passageway extends along a circular path and encircles the first cooling passageway.

5. The wafer support structure of claim 1, wherein the main body also defines a coolant inlet hole open at the exterior of the main body so that coolant can be fed into the main body via the coolant inlet hole, the first coolant passage is connected to the coolant inlet hole, and the second cooling passageway branches from the first cooling passageway proximate the location of the coolant inlet hole.

6. The wafer support structure of claim 1, wherein the main body also defines a first coolant outlet hole connected to the first cooling passageway and open at the exterior of the main body such that coolant flowing along the first cooling passageway can be discharged from the main body via the first coolant outlet hole, and a second coolant outlet hole connected to the second cooling passageway and open at the exterior of the main body such that coolant flowing along the second passageway path can be discharged from the main body via the second coolant outlet hole.

7. The wafer support structure of claim 1, wherein said wafer support also includes a lower electrode fixed to the bottom of said main body.

8. A wafer support of semiconductor wafer processing equipment, comprising:
a main body having a first top surface at a central portion thereof and configured to support a wafer, and a second top surface extending around the first top surface at a level beneath that at which the first top surface is disposed, whereby an upper portion of the main body is stepped so that an outer peripheral portion of a wafer supported by the first top surface will protrude beyond the outer periphery of the first top surface, and
the cooling passage including a first cooling passageway running directly beneath the first top surface such that coolant flowing through the first cooling passageway will cool a wafer resting on the first top surface, and a second cooling passageway running directly beneath the second top surface.

9. The wafer support of claim 8, wherein the first top surface of the main body has a circular outer periphery, and the first cooling passageway has a circular section running approximately directly under the circular periphery of the first top surface of the main body, and a cross-shaped section located radially inwardly of the circular section.

10. The wafer support of claim 8, wherein the second cooling passageway extends along a circular path and encircles the first cooling passageway.

11. The wafer support of claim 8, wherein the main body also defines a coolant inlet hole open at the exterior of the main body so that coolant can be fed into the main body via the coolant inlet hole, the first coolant passage is connected to the coolant inlet hole, and the second cooling passageway branches from the first cooling passageway proximate the location of the coolant inlet hole.

12. The wafer support of claim 8, wherein the main body also defines a first coolant outlet hole connected to the first cooling passageway and open at the exterior of the main body such that coolant flowing along the first cooling passageway can be discharged from the main body via the first coolant outlet hole, and a second coolant outlet hole connected to the second cooling passageway and open at the exterior of the main body such that coolant flowing along the second passageway path can be discharged from the main body via the second coolant outlet hole.

13. The wafer support of claim 8, and further comprising a lower electrode fixed to the bottom of said main body.

14. Plasma processing equipment comprising:
a reaction chamber having a gas inlet through which process gas is introduced into the chamber, and a gas outlet through which gas in the chamber is exhausted;
a plasma generator that converts the process gas introduced into the reaction chamber into plasma when power is supplied thereto; and
wafer support structure disposed within said reaction chamber, the wafer support structure including a wafer support on which a wafer to be processed by the plasma is to be supported, and a focus ring that focuses the plasma on the wafer supported by the wafer support,
the wafer support including a main body having a first top surface configured to support the wafer, and a second top surface extending around the first top surface, the focus ring being disposed directly over the second top surface, and said main body defining a cooling passage therein,
the cooling passage including a first cooling passageway running directly beneath the first top surface such that coolant flowing through the first cooling passageway will cool a wafer resting on the first top surface, and a second cooling passageway running directly beneath the second top surface such that coolant flowing through the second cooling passageway will cool the focus ring.

15. The plasma processing equipment of claim 14, wherein the focus ring has a first top surface, and a second top surface that is substantially coplanar with the first top surface of the main body of the wafer support, the second top surface of the focus ring being disposed at a level beneath that at which the first top surface of the focus ring is disposed.

16. The plasma processing equipment of claim 15, wherein the first top surface of the main body of the wafer support has a circular outer periphery, and the first cooling passageway has a circular section running approximately directly under the circular periphery of the first top surface of the main body, and a cross-shaped section located radially inwardly of the circular section.

17. The plasma processing equipment of claim 15, wherein the second cooling passageway extends along a circular path and encircles the first cooling passageway.

18. The plasma processing equipment of claim 15, wherein the main body of the wafer support also defines a coolant inlet hole open at the exterior of the main body so that coolant can be fed into the main body via the coolant inlet hole, the first coolant passage is connected to the coolant inlet hole, and the second cooling passageway branches from the first cooling passageway proximate the location of the coolant inlet hole.

19. The plasma processing equipment of claim 15, wherein the main body of the wafer support also defines a first coolant outlet hole connected to the first cooling passageway and open at the exterior of the main body such that coolant flowing along the first cooling passageway can be discharged from the main body via the first coolant outlet hole, and a second coolant outlet hole connected to the second cooling passageway and open at the exterior of the main body such that coolant flowing along the second passageway path can be discharged from the main body via the second coolant outlet hole.

20. The plasma processing equipment of claim 15, wherein said wafer support also includes a lower electrode fixed to the bottom of said main body.
